(19) United States
(12) Patent Application Publication
(10) Pub. No.: US 2026/0248047 A1
(43) Pub. Date: Aug. 20, 2026

(54) SEMICONDUCTOR DEVICES WITH SELECTIVELY DISABLED BOND PADS FOR CASCADE WIRE BONDING

(71) Applicant: Micron Technology, Inc., Boise, ID (US)

(72) Inventors: Kimball D. Lowry, Boise, ID (US); Avishesh Dhakal, Meridian, ID (US)

(21) Appl. No.: 19/450,616

(22) Filed: Jan. 15, 2026

Related U.S. Application Data
(60) Provisional application No. 63/760,531, filed on Feb. 19, 2025.

(51) Int. Cl. H10W 90/24; H10B 80/00; H10W 72/00; H10W 72/50; H10W 72/90; H10W 90/00

(52) U.S. Cl. CPC H10W 90/24; H10B 80/00; H10W 72/01961; H10W 72/5473; H10W 72/967; H10W 90/752; H10W 90/754

(57) ABSTRACT

Semiconductor devices with selectively disabled bond pads for cascade wire bonding (and associated systems, devices, and methods) are disclosed herein. In one embodiment, a semiconductor device includes a substrate having a bond finger, a stack of semiconductor dies disposed on the substrate, and a cascaded wire bond. The stack can include a first semiconductor die and a second semiconductor die disposed over the first semiconductor die. The first semiconductor die can include a dummy pad, and the second semiconductor die can include a bond pad. The cascaded wire bond can couple the bond pad to the bond finger via the dummy pad. The semiconductor device can further include circuitry configured to convert a bond pad of the first semiconductor die into the dummy pad.

### CROSS-REFERENCE TO RELATED APPLICATION(S)

The present application claims priority to U.S. Provisional Patent Application No. 63/760,531, filed February 19, 2025, the disclosure of which is incorporated herein by reference in its entirety.

### TECHNICAL FIELD

The present disclosure relates generally to semiconductor packaging. For example, several embodiments described in greater detail below relate generally to semiconductor devices with selectively disabled bond pads for cascade wire bonding in stacked memory die configurations.

### BACKGROUND

Semiconductor devices have become increasingly complex and miniaturized over the years, with a growing demand for higher performance and greater functionality in smaller form factors. One approach to meeting these demands has been the development of three-dimensional (3D) packaging technologies, which allow for the stacking of multiple semiconductor dies within a single package. This vertical integration enables higher component density, leading to improved performance.

Wire bonding remains a widely used and cost-effective method for electrically connecting semiconductor dies to package substrates or other dies within a stack. As die stacks become taller and more intricate, however, traditional wire bonding techniques face challenges in terms of wire length, loop height, and overall bonding area requirements. These challenges can impact package reliability, electrical performance, and manufacturing yield.

In memory devices, such as dynamic random-access memory (DRAM), the concept of byte mode operation has been employed to increase packaging density and flexibility. Byte mode operation in a semiconductor package can include assigning each memory die in a stack to a single byte or channel. In particular, byte mode can allow a memory die to operate using only data input/output (I/O) terminals corresponding to the assigned byte or channel, with other data I/O terminals of the memory die going unused. While byte mode offers advantages in terms of density, it also introduces complexities in wire bonding arrangements, particularly when stacking dies corresponding to different bytes.

### BRIEF DESCRIPTION OF THE DRAWINGS

Many aspects of the present technology can be better understood with reference to the following drawings. The components in the drawings are not necessarily to scale. Instead, emphasis is placed on illustrating clearly the principles of the present disclosure.

FIG. 1 is a partially schematic, top perspective view of a semiconductor device.

FIG. 2 is a partially schematic, top perspective view of a semiconductor device configured in accordance with various embodiments of the present technology.

FIG. 3 is a partially schematic side view of another semiconductor device configured in accordance with various embodiments of the present technology.

FIG. 4 is a partially schematic side view of still another semiconductor device configured in accordance with various embodiments of the present technology.

FIG. 5 is a partially schematic side view of yet another semiconductor device configured in accordance with various embodiments of the present technology.

### DETAILED DESCRIPTION

The present technology relates to semiconductor devices with stacked memory die configurations that utilize selectively disabled bond pads for cascade wire bonding. By converting active pads into dummy pads through methods such as fuse blowing or bond options, more efficient wire routing and reduced wire lengths may be achieved. This approach may allow for more compact packaging, improved electrical performance, and potentially reduced manufacturing costs. The technology may be particularly beneficial in memory devices operating in byte mode, where unused data I/O terminals can be repurposed as dummy pads to optimize wire bonding arrangements.

In the following description, specific details are set forth to provide a thorough understanding of aspects of the present technology. One skilled in the relevant art will recognize, however, that the systems, devices, and techniques described herein can be practiced without one or more of the specific details set forth herein, or with other methods, components, materials, etc.

Reference throughout this specification to an “example” or an “embodiment” means that a particular feature, structure, or characteristic described in connection with the example or embodiment is included in at least one example or embodiment of the present technology. Thus, use of the phrases “for example,” “as an example,” or “an embodiment” herein are not necessarily all referring to the same example or embodiment and are not necessarily limited to the specific example or embodiment discussed. Furthermore, features, structures, or characteristics of the present technology described herein may be combined in any suitable manner to provide further examples or embodiments of the present technology.

Spatially relative terms (e.g., “beneath,” “below,” “over,” “under,” “above,” “upper,” “top,” “bottom,” “left,” “right,” “center,” “middle,” and the like) may be used herein for ease of description to describe one element’s or feature’s relationship relative to one or more other elements or features as illustrated in the figures. It will be understood that the spatially relative terms are intended to encompass different orientations of a device or system in use or operation, in addition to the orientation depicted in the figures. For example, if a device or system illustrated in the figures is rotated, turned, or flipped about a horizontal axis, elements or features described as “below” or “beneath” or “under” one or more other elements or features may then be oriented “above” the one or more other elements or features. Thus, the exemplary terms “below” and “under” are non-limiting and can encompass both an orientation of above and below. The device or system may additionally, or alternatively, be otherwise oriented (e.g., rotated ninety degrees about a vertical axis, or at other orientations) than illustrated in the figures, and the spatially relative descriptors used herein are interpreted accordingly. In addition, it will also be understood that when an element is referred to as being “between” two other elements, it can be the only element between the two other elements, or one or more intervening elements may also be present.

### A. Overview

As discussed above, many semiconductor memory devices utilize stacked die configurations to increase packaging density and functionality. In many of these package configurations, the number of dies in a stack exceeds the number of available package channels, and wire bonding is used to electrically connect the stacked die to the package substrate. Several such configurations utilize a communication method called byte mode in which (a) each memory die is assigned to a single byte or package channel and (b) only data (DQ) terminals on each memory die corresponding to the assigned byte or package channel are used to access data on that memory die, with other DQ terminals going unused (e.g., not connected to the package substrate via a wire bond). Because different bytes can be accessed separately or simultaneously, byte mode can allow for more efficient use of package channels when the number of dies exceeds the number of available channels.

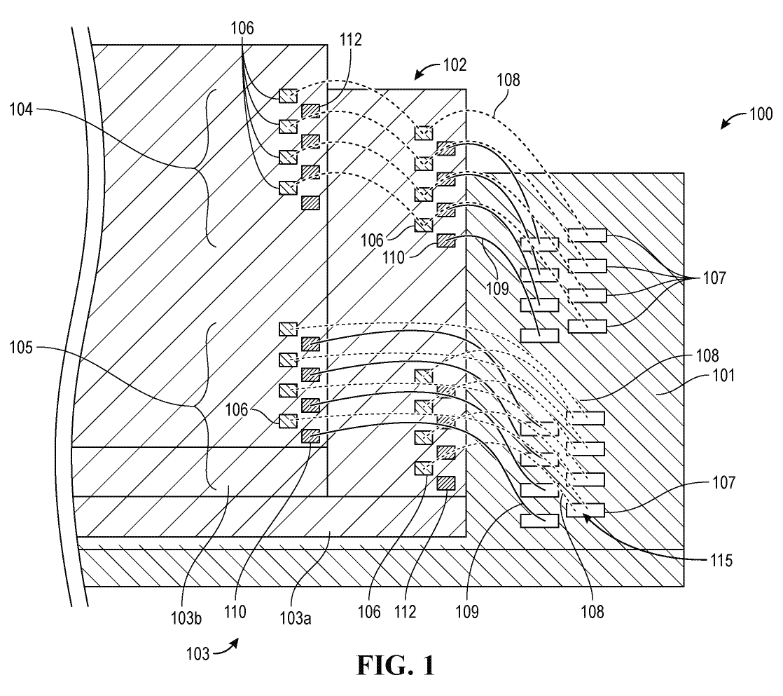

Byte mode, however, can introduce its own set of complications in wire bonding arrangements. For example, consider FIG. 1 that illustrates a partially schematic, top perspective view of a semiconductor device 100. As shown, the semiconductor device 100 includes a package substrate 101 and a stack 102 of semiconductor dies 103 (identified individually in FIG. 1 as first memory die 103a and second memory die 103b) disposed on the package substrate 101. The package substrate 101 includes a plurality of bond fingers 107. In addition, each of the first and second memory dies 103a and 103b includes (i) a plurality of power (e.g., VDD, VSS) bond pads 106 and (ii) a plurality of data (DQ) bond pads 110, 112.

For the sake of clarity and understanding, the plurality of DQ bond pads 110, 112 are arranged in FIG. 1 such that (a) DQ bond pads 110, 112 corresponding to a first byte 104 are positioned closer to the top of the drawings page on each of the first and second memory dies 103a and 103b, and (b) DQ bond pads 110, 112 corresponding to a second byte 105 are arranged closer to the bottom of the drawings page on each of the first and second memory dies 103a and 103b. In addition, although a byte commonly corresponds to eight (8) DQ bond pads, only a nibble (or four (4) DQ bond pads) is shown for each of the first and second bytes 104 and 105 for the sake of clarity. Furthermore, bond pads for other signals (e.g., command/address (CA) signals, chip select (CS) signals) and corresponding bond fingers and wire bonds are omitted from FIG. 1 to avoid unnecessarily obscuring aspects of the illustrated wire bond arrangement. Additionally, for the sake of clarity, the bond fingers 107 are shown in FIG. 1 to be in parallel with each other and in line with the corresponding power and DQ bond pads 106, 110, 112. It should be understood, however, that it is common for bond fingers and bond pads to be out of alignment with each other. It is also common for bond fingers to be placed at an angle on a package substrate relative to stack of semiconductor dies on the package substrate. Thus, as shown in FIG. 1, the wire bonds 108, 109 do not cross over each other, but it is appreciated that, in reality, the wire bonds 108, 109 likely would, especially in configurations that employ bond fingers 107 that are out of alignment with and/or positioned at an angle with respect to bond pads 106, 110, 112.

In FIG. 1, the first memory die 103a is assigned to the first byte 104. Thus, each of the DQ bond pads 110 of the first memory die 103a that correspond to the first byte 104 is coupled to a corresponding one of the bond fingers 107 on the package substrate 101 via a corresponding wire bond 109 (also referred to herein as a “data (DQ) wire bond”) and is used to access data on the first memory die 103a. Because the first memory die 103a corresponds to the first byte 104 and not the second byte 105, each of the DQ bond pads 112 of the first memory die 103a that correspond to the second byte 105 (although active and connected to circuitry internal the first memory die 103a) is not connected to a bond finger 107 on the package substrate 101 and/or is not used to access data on the first memory die 103a. Reference number 110 is used in FIG. 1 to denote an active DQ bond pad that is coupled to a bond finger 107 on the package substrate 101 and used to access data, and reference number 112 is used in FIG. 1 to denote an active DQ bond pad that is not coupled to a bond finger 107 on the package substrate 101 and not used to access data.

By contrast, the second memory die 103b is assigned to the second byte 105. Thus, each of the DQ bond pads 110 of the second memory die 103b that corresponds to the second byte 105 is coupled to a corresponding one of the bond fingers 107 on the package substrate 101 via a corresponding wire bond 109 and is used to access data on the second memory die 103b. Because the second memory die 103b corresponds to the second byte 105 and not the first byte 104, each of the DQ bond pads 112 of the second memory die 103b that correspond to the first byte 104 (although active and connected to circuitry internal the second memory die 103b) is not connected to a bond finger 107 on the package substrate and not used to access data.

Referring now to the power bond pads 106, each of the power bond pads 106 on both the first and second memory dies 103a and 103b is coupled to a corresponding bond finger 107 on the package substrate 101 regardless of whether it is positioned adjacent DQ bond pads 110, 112 corresponding to the first byte 104 or the second byte 105. In FIG. 1, the power bond pads 106 positioned adjacent DQ bond pads 110, 112 corresponding to the first byte 104 are coupled to corresponding bond fingers 107 via cascading wire bonds 108. The wire bonds 108 are also referred to herein as "power wire bonds." The lower portions of the cascading wire bonds 108 (extending from the first memory die 103a to the package substrate 101) are generally aligned with the wire bonds 109 coupling the DQ bond pads 110 on the first memory die 103a to bond fingers 107 on the package substrate 101 and can therefore provide shielding to these wire bonds 109.

By contrast, the power bond pads 106 of the first and second memory dies 103a and 103b that are positioned adjacent DQ bonds pads 110, 112 corresponding to the second byte 105 are each coupled directly to a corresponding bond finger 107 via a wire bond 108. More specifically, the power bond pads 106 of the first memory die 103a that are positioned adjacent DQ bond pads 112 on the first memory die 103a are coupled directly to corresponding bond fingers 107 on the package substrate 101 via wire bonds 108 having a smaller loop/shorter length. In addition, the power bond pads 106 of the second memory die 103b that are positioned adjacent DQ bond pads 110 on the second memory die 103b are coupled directly to corresponding bond fingers 107 on the package substrate 101 via wire bonds 108 having a larger loop/longer length.

As shown in FIG. 1, the wire bonds 108 that are used to directly couple the power bond pads 106 positioned adjacent the DQ bond pads 110, 112 corresponding to the second byte 105 are arranged in pairs of one longer wire bond 108 and one shorter wire bond 108, with each wire bond 108 of a pair coupled to a same bond finger 107 on the package substrate 101 (as shown, for example, at location 115). Use of a pair of wire bonds 108 in this manner is commonly referred to as "high/low looping," and can be used in the arrangement shown in FIG. 1 to (a) couple a power bond pad 106 on the first memory die 103a and a power bond pad 106 on the second memory die 103b to a corresponding bond finger 107 on the package substrate 101 while (b) providing shielding (using the larger loop wire bonds 108) to wire bonds 109 that couple DQ bond pads 110 on the second memory die 103b to corresponding bond fingers 107 on the package substrate 101. Stated another way, cascaded wire bonds are not used to couple the power bond pads 106 positioned adjacent the DQ bond pads 110, 112 of the second byte 105 because it is expected that such cascaded wire bonds, being positioned lower/out of alignment with the wire bonds 109 that couple the DQ bond pads 110 on the second memory die 103b to corresponding bond fingers 107 on the package substrate 101, would not provide sufficient shielding to these wire bonds 109.

The wire bond arrangement illustrated in FIG. 1 is associated with several risks and drawbacks. For example, given the number and lengths of the wire bonds 108, 109, it is not uncommon in this arrangement for wire bonds 108, 109 to cross over one another, creating a risk that the crossing wire bonds 108, 109 become shorted with one another. Furthermore, use of high/low looping often requires multiple wire bonds 108 being connected to a same bond finger 107 on the package substrate 101. Multiple connections (or "tacks") to the same bond finger 107 requires use of a longer bond finger 107 to accommodate the multiple connections. In addition, multiple connections to the same bond finger 107 risks at least one of the wire bonds 108 being established with the corresponding wire being positioned out of alignment and/or at a non-parallel angle with the bond finger 107, increasing the risk of that wire bond 108 failing. Moreover, the longer lengths of several of the wire bonds 108, 109 are associated with longer signal paths and/or with larger loops that extend a larger distance away from the stack 102 and/or the package substrate 101. Additionally, the relatively large number and lengths of the wire bonds 108, 109 is associated with higher costs than other wire bond arrangements.

To address at least some of these concerns, the present technology is generally directed to semiconductor devices with stacked semiconductor die configurations that utilize selectively disabled bond pads to enable use of cascade wire bonding, such as for DQ bond pads, power (e.g., VDD, VSS) bond pads, or both. For example, the technology allows for converting active and/or unused bond pads (e.g., unused DQ bond pads while a semiconductor device operates in byte mode) into dummy bond pads through methods such as fuse blowing or bond options, enabling more efficient wire routing and reduced wire lengths for connecting bond pads on memory dies higher in a stack to a package substrate. As a specific example, a semiconductor device (e.g., a memory device) of the present technology can comprise a plurality of stacked semiconductor dies (e.g., memory dies), a package substrate, and a plurality of wire bonds connecting each of the stacked semiconductor dies to the substrate. At least one of the semiconductor dies in the stack can include at least one active bond pad that is unused (e.g., when the semiconductor device operates in byte mode) and that can be selectively disabled (e.g., using a fuse, using a bond option, using internal circuitry of the semiconductor die) to function as a dummy pad for cascade wire bonding a bond pad of a semiconductor die positioned higher in the stack to the substrate. Continuing with this example, the semiconductor device can further employ cascaded wire bonds to (a) couple power bond pads to the package substrate and (b) shield the cascaded wire bonds that are coupled to the dummy pad.

The present technology is expected to offer several advantages over other wire bond designs, such as the wire bond design described above with reference to FIG. 1. For example, the present technology is expected to reduce wire bonding package footprints in comparison to other wire bond designs. In particular, by enabling cascade wire bonding through selectively disabled bond pads, the technology allows for more compact wire routing and/or a more compact bond shell. This reduction in footprint enables larger dies or larger die stack footprints to fit within existing package sizes, or alternatively, allows for shrinkage of semiconductor device form factors. The more efficient wire routing also leads to better overall performance, with fewer wires used and shorter wire lengths.

As another example, the present technology is expected to offer substantial benefits in terms of package assembly costs and manufacturability. More specifically, the present technology is expected to employ fewer wire bonds in comparison to other wire bonding designs, thereby enabling improvements in assembly throughput. In addition, the present technology is expected to reduce the lengths/amount of wire used, thereby reducing manufacturing costs. Furthermore, the present technology is expected to improve yield of fully functioning semiconductor devices and improve reliability of such devices. In particular, use of cascade wire bonding and a single tack per bond finger in place of high/low looping and/or multiple tacks for a same bond finger is expected to result in better wire-to-bond-finger alignment and reduced wire-over-wire interference, minimizing the potential for failed connections and short circuits, respectively.

As still another example, the present technology is expected to increase substrate design versatility, allowing a single substrate design to accommodate high-density package designs while also supporting derivative densities. For example, the present technology is expected to enable a substrate designed for a 16-die package to also be used with other memory die densities, such as 12-die packages or 8-die packages. Such versatility, combined with the reduced wire material usage and smaller form factor fitment due to compact bond-shells and shorter finger lengths, is expected to further reduce manufacturing and/or assembly costs.

As yet another example, the present technology is expected to achieve improved performance in comparison to other wire bonding designs. More specifically, the present technology enables bond fingers to be positioned closer to the die. As a result, the present technology enables use of shorter wires and therefore shorter signal paths.

B.Selected Embodiments of Semiconductor Devices with Selectively Disabled Bond Pads for Cascade Wire Bonding, and Associated Systems, Devices, and Methods

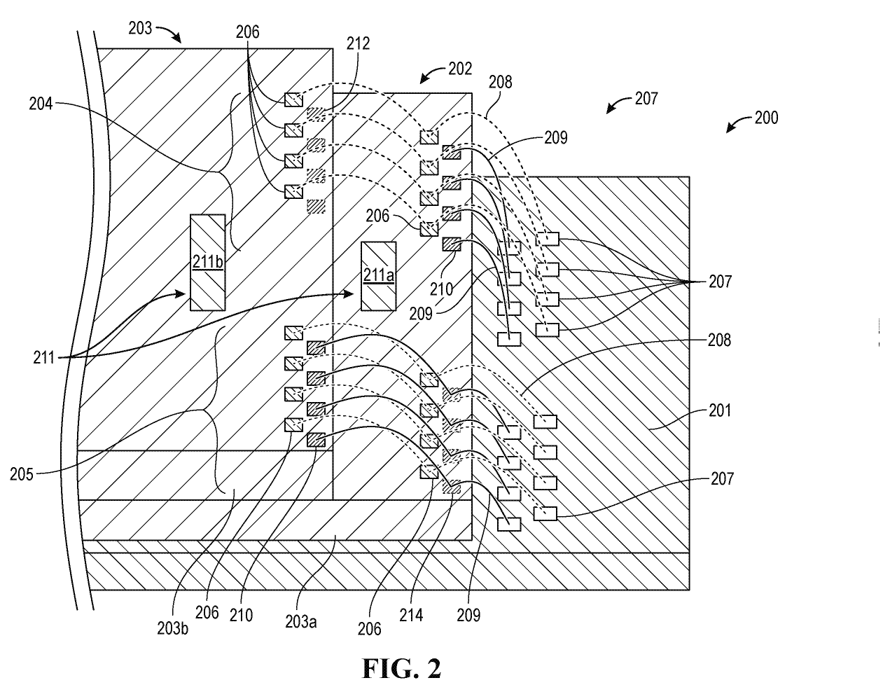

FIG. 2 is a partially schematic, top perspective view of a semiconductor device 200 (e.g., a memory device) configured in accordance with various embodiments of the present technology. As shown, the semiconductor device 200 includes a package substrate 201 and a stack 202 of semiconductor dies 203 (identified individually in FIG. 2 as first memory die 203a and second memory die 203b) disposed on the package substrate 201. The package substrate 201 includes a plurality of bond fingers 207. In addition, each of the first and second memory dies 203a and 203b includes (i) a plurality of power (e.g., VDD, VSS) bond pads 206 and (ii) a plurality of data (DQ) bond pads 210, 212, 214. As will become apparent from the description of FIG. 2 below, reference number 210 is used in FIG. 2 to denote an active DQ bond pad that is coupled to the package substrate 201 and used to access data on the corresponding semiconductor die 203; reference number 212 is used to denote an active DQ bond pad that is not coupled to the package substrate 201 and/or is not used to access data on the corresponding semiconductor die 203; and reference number 214 is used to denote a dummy (or inactive) DQ bond pad that has been selectively disabled from being used to access data on the corresponding semiconductor die 203.

For the sake of clarity and understanding, the plurality of DQ bond pads 210, 212, 214 are arranged in FIG. 2 such that (a) DQ bond pads 210, 212 corresponding to a first byte 204 are positioned closer to the top of the drawings page on each of the first and second memory dies 203a and 203b, and (b) DQ bond pads 210, 214 corresponding to a second byte 205 are arranged closer to the bottom of the drawings page on each of the first and second memory dies 203a and 203b. In addition, although a byte commonly corresponds to eight (8) DQ bond pads, only a nibble (or four (4) DQ bond pads) is shown for each of the first and second bytes 204 and 205 in FIG. 2 for the sake of clarity. Furthermore, bond pads for other signals (e.g., command/address (CA) signals, chip select (CS) signals) and corresponding bond fingers and wire bonds are omitted from FIG. 2 to avoid unnecessarily obscuring aspects of the present technology.

As shown in FIG. 2, the semiconductor device 200 further includes circuitry 211. More specifically, in the illustrated example, the first memory die 203a includes first circuitry 211a, and the second memory die 203b includes second circuitry 211b. The first circuitry 211a is configured to selectively disable (e.g., convert, repurpose) one or more of the DQ bond pads 210, 212 of the first memory die 203a into dummy pads 214, and the second circuitry 211b is configured to selectively disable one or more of the DQ bond pads 210, 212 of the second memory die 203b into dummy pads 214.

For example, the first circuitry 211a and/or the second circuitry 211b can include one or more bond options of the first and/or second memory dies 203a and/or 203b, respectively. Continuing with this example, DQ bond pads 210, 212 of the first memory die 203a and/or the second memory die 203b can be converted to dummy pads 214 depending on how the bond option(s) of the first circuitry 211a and/or the second circuitry 211b, respectively, are connected (e.g., whether the bond option(s) are connected to a power supply voltage (e.g., VDD) or ground (e.g., VSS), or are left floating). As a specific example, connecting the one or more bond options of the first circuitry 211a to ground can convert DQ bond pads 210, 212 of the first memory die 203a that correspond to the first byte 204 into dummy pads 214, and connecting the one or more bond options of the first circuitry 211a to a power supply voltage can convert DQ bond pads 210, 212 of the first memory die 203a that correspond to the second byte 205 into dummy pads 214. Dummy pads 214 on the first memory die 203a can be DQ bond pads 210, 212 that have been disconnected from internal circuitry of the first memory die 203a and/or that have been otherwise disabled from being used to access data on the first memory die 203a. Leaving the one or more bond options of the first circuitry 211a floating can leave the DQ bond pads 210, 212 active, connected to internal circuitry of the first memory die 203a, and/or usable to access data on the first memory die 203a. The second circuitry 211b can be similarly used to selectively disable one or more DQ bond pads 210, 212 of the second memory die 203b. Other arrangements are of course possible and within the scope of the present technology. For example, DQ bond pads of the first memory die 203a can be dummy pads 214 by default (e.g., when the one or more bond options of the first circuitry 211a are floating) and can be selectively activated/enabled and converted into DQ bond pads 210, 212 that are usable to access data on the first memory die 203a when the one or more bond options of the first circuitry 211a are coupled to a voltage, such as a power supply voltage or ground.

As another example, the first circuitry 211a and/or the second circuitry 211b can include fuse options. One or more of the fuse options can be blown to selectively disable one or more of the DQ bond pads 210, 212. As a specific example, the first circuitry 211a can include (a) a first fuse corresponding to DQ bond pads 210, 212 of the first byte 204 and (b) a second fuse corresponding to DQ bond pads 210, 212 of the second byte 205. Continuing with this example, DQ bond pads 210, 212 of the first memory die 203a can be active (e.g., connected to internal circuitry of the first memory die 203a and/or usable to access data on the first memory die 203a) by default. When the first fuse of the first circuitry 211a is blown, the DQ bond pads 210, 212 of the first memory die 203a corresponding to the first byte 204 can be converted to dummy pads 214 that are disconnected from internal circuitry of the first memory die 203a and/or are otherwise disabled from being used to access data on the first memory die 203a. When the second fuse of the first circuitry 211a is blown, the DQ bond pads 210, 212 of the first memory die 203a corresponding to the second byte 205 can be converted to dummy pads 214 that are disconnected from internal circuitry of the first memory die 203a and/or are otherwise disabled from being used to access data on the first memory die 203a. The second circuitry 211b can be similarly used to selectively disable one or more DQ bond pads 210, 212 of the second memory die 203b. Other arrangements are of course possible and within the scope of the present technology. For example, the first circuitry 211a can include a fuse for each DQ bond pad 210, 212 of the first memory die 203a, and the DQ bond pads 210, 212 can be individually converted to dummy pads 214 by blowing a corresponding fuse of the first circuitry 211a.

As still another example, the first circuitry 211a and/or the second circuitry 211b can include a switch network or other circuitry that can be controlled to selectively disable (or selectively enable) one or more bond pads 210, 212 of the first memory die 203a and/or the second memory die 203b, respectively. As a specific example, each of the DQ bond pads 210, 212 of the first memory die 203a can be selectively coupled to internal circuitry of the first memory die 203a and/or usable to access data on the first memory die 203a via one or more switches of the first circuitry 211a. Continuing with this example, the first circuitry 211a can be programmed or otherwise controlled to selectively deactivate one or more switches of the switch network to convert one or more of the DQ bond pads 210, 212 (e.g., DQ bond pads 210, 212 corresponding to the first byte 204 and/or DQ bond pads 210, 212 corresponding to the second byte 205) from internal circuitry or otherwise disable them from being used to access data on the first memory die 203a. Additionally, or alternatively, the first circuitry 211a can be programmed or otherwise controlled to selectively activate one or more switches of the switch network to activate/enable one or more of the DQ bond pads 210, 212 (e.g., DQ bond pads 210, 212 corresponding to the first byte 204 and/or DQ bond pads 210, 212 corresponding to the second byte 205) to access data on the first memory die 203a, such as by connecting them to internal circuitry of the first memory die 203a. The second circuitry 211b can be similarly used to selectively disable (or selectively enable) one or more DQ bond pads 210, 212 of the second memory die 203b.

In some embodiments, the deactivation or activation of a DQ bond pad 210, 212 using the first circuitry 211a or the second circuitry 211b can be permanent, such as in implementations in which the deactivation or activation is achieved via a bond option or a fuse blow of the first circuitry 211a and/or the second circuitry 211b. As another example, in implementations in which the first circuitry 211a and/or the second circuitry 211b includes a switch network, a DQ bond pad 210, 212 can be converted to a dummy pad 214 indefinitely using the switch network. Permanent and/or indefinite conversion of one or more DQ bond pads 210, 212 into dummy pad(s) 214 can be referred to herein as operating the semiconductor device 200 in accordance with a static mode of operation (e.g., during which DQ bond pads 210, 212 are not toggled between being configured as a dummy pad 214 and being configured as an active bond pad 210, 212). Alternatively, the deactivation or activation of a DQ bond pad 210, 212 using the first circuitry 211a or the second circuitry 211b can be temporary or reversible. For example, in implementations in which (a) the first circuitry 211a and/or the second circuitry 211b includes a switch network and (b) a DQ bond pad 210, 212 is converted to a dummy pad 214 by deactivating a switch of the switch network, the dummy pad 214 can be converted back to a DQ bond pad 210, 212 by reactivating the switch. In some embodiments, a DQ bond pad 210, 212 can be toggled between being configured as a dummy pad 214 and being configured as an active bond pad 210, 212, such as during operation of the semiconductor device 200. Dynamic conversion of one or more DQ bond pads 210, 212 into dummy pad(s) 214 can be referred to herein as operating the semiconductor device 200 in accordance with a dynamic mode of operation (e.g., during which DQ bond pads 210, 212 can be toggled back and forth between being configured as a dummy pad 214 and being configured as an active bond pad 210, 212). Temporary or reversible activation or deactivation of DQ bond pads 210, 212, 214 can be particularly useful in implementations in which the semiconductor device 200 can be toggled between operating modes, such as in and out of byte mode.

The first circuitry 211a and/or the second circuitry 211b can be leveraged to enable certain wire bonding designs of the present technology that are useful for coupling the first memory die 203a and/or the second memory die 203b to the package substrate 201. For example, with continuing reference to the embodiment illustrated in FIG. 2, the semiconductor device 200 is configured to operate in byte mode, and the first memory die 203a has been assigned to the first byte 204. Thus, each of the DQ bond pads 210 of the first memory die 203a that correspond to the first byte 204 (a) is coupled to a corresponding one of the bond fingers 207 on the package substrate 201 via a corresponding wire bond 209 and (b) is usable to access data on the first memory die 203a.

In addition, because the first memory die 203a corresponds to the first byte 204 and not the second byte 205, the DQ bond pads of the first memory die 203a that correspond to the second byte 205 are not used to access data on the first memory die 203a (at least while the semiconductor device 200 operates in byte mode). Thus, as shown in FIG. 2, each of the DQ bond pads of the first memory die 203a that correspond to the second byte 205 can be converted into a dummy pad 214 using the first circuitry 211a. As discussed above, dummy pads 214 can be DQ bond pads that are disconnected from internal circuitry (e.g., I/O circuitry) within the corresponding semiconductor die 203 (here, the first memory die 203a) and/or that are otherwise disabled from being used to access data on the corresponding semiconductor die 203.

Conversion of the DQ bond pads on the first memory die 203a into dummy pads 214 differs from the implementation illustrated in FIG. 1 because, rather than leaving the DQ bond pads that correspond to the second byte 205 active and unused/unconnected, these DQ bond pads are specifically disconnected from internal circuitry of the first memory die 203a (or are otherwise specifically disabled from being used to access data on the first memory die 203a) such that they can be used with cascaded wire bonds 209 to connect DQ bond pads 210 of a semiconductor die 203 (e.g., the second memory die 203b) positioned higher in the stack 202 to corresponding bond fingers 207 on the package substrate 201. More specifically, similar to the second memory die 103b in the implementation illustrated in FIG. 1, the second memory die 203b in FIG. 2 has been assigned to the second byte 205. Thus, each of the DQ bond pads 210 of the second memory die 203b that correspond to the second byte 205 is coupled to a corresponding one of the bond fingers 207 on the package substrate 201 via a corresponding wire bond 209 and is usable to access data on the second memory die 203b. Unlike the implementation illustrated in FIG. 1, however, the wire bonds 209 coupled to the DQ bond pads 210 of the second memory die 203b in FIG. 2 are cascaded down to the corresponding bond fingers 207 on the package substrate 201 using the dummy pads 214 on the first memory die 203a. Because the dummy pads 214 on the first memory die 203a are disconnected from the internal circuitry of the first memory die 203a and/or are otherwise disabled from accessing data on the first memory die 203a, the DQ bond pads 210 of the second memory die 203b can be safely connected to corresponding bond fingers 207 on the package substrate 201 using the dummy pads 214 without risk of accessing data on the first memory die 203a using signals transmitted over the second byte 205.

Use of dummy pads 214 and cascaded wire bonds 209 to couple the DQ bond pads 210 of the second memory die 203b to corresponding bond fingers 207 on the package substrate 201 in the implementation illustrated in FIG. 2 is expected to achieve several of the advantages of the present technology described above. For example, in comparison to the implementation illustrated in FIG. 1 in which the DQ bond pads 110 of the second memory die 103b are directly bonded to bond fingers 107 on the package substrate 101 using wire bonds 109, use of cascaded wire bonds 209 like those shown in FIG. 2 is expected to shorten the overall lengths of the wire bonds 209, thereby shortening the signal path (improving performance) and reducing manufacturing costs. In addition, use of cascaded wire bonds 209 in lieu of direct wire bonds is also expected to achieve more compact wire routing, which may reduce the risk of wire bonds crossing and shorting.

Referring now to the power bond pads 206 shown in FIG. 2, each of the power bond pads 206 on both the first and second memory dies 203a and 203b is coupled to a corresponding one of the bond fingers 207 on the package substrate 201 regardless of whether it is positioned between DQ bond pads 210, 212 or dummy pads 214 corresponding to the first byte 204 or the second byte 205. For example, the power bond pads 206 positioned adjacent the DQ bond pads 210, 212 corresponding to the first byte 204 in FIG. 2 can be coupled to corresponding bond fingers 207 via cascading wire bonds 208, similar to the power bond pads 106 positioned adjacent the bond pads 110, 112 corresponding to the first byte 104 in FIG. 1. The lower portions of these cascading wire bonds 208 in FIG. 2 can be generally aligned with the wire bonds 209 coupling the DQ bond pads 210 on the first memory die 203a to bond fingers 207 on the package substrate 201 and are therefore expected to provide shielding to these wire bonds 209.

Unlike the example in FIG. 1, however, the power bond pads 206 of the first and second memory dies 203a and 203b that are positioned adjacent DQ bonds pads 210 and dummy pads 214 corresponding to the second byte 205 are each also coupled to a corresponding one of the bond fingers 207 via a cascaded wire bond 208. Use of the cascaded wire bonds 208 to couple these power bond pads 206 to bond fingers 207 on the package substrate 201 can be enabled via use of the cascaded wire bonds 209 that couple the DQ bond pads 210 of the second memory die 203b to bond fingers 207 on the package substrate 201 via the dummy pads 214 on the first memory die 203a. More specifically, because the dummy pads 214 on the first memory die 203a enable use of compact, cascaded wire bonds 209 to couple DQ bond pads 210 on the second memory die 203b to corresponding bond fingers 207 on the package substrate 201 (e.g., in lieu of large-looped wire bonds, such as the large-looped wire bonds 109 of FIG. 1 that directly couple the DQ bond pads 110 on the second memory die 103b to the corresponding bond fingers 107 in FIG. 1), the power bond pads 206 positioned adjacent to the DQ bond pads 210 and dummy pads 214 that correspond to the second byte 205 can similarly be coupled to corresponding bond fingers 207 on the package substrate 201 using cascaded wire bonds 208 while keeping these cascaded wire bonds 208 generally aligned with the cascaded wire bonds 209 to provide shielding to the cascaded wire bonds 209.

In other words, the present technology is expected to obviate the use of high/low looping described above with reference to FIG. 1, replacing the pair of wires used in high/low looping with a single cascaded wire bond 208. In turn, the present technology is expected to facilitate using a single (e.g., only one) connection (or tack) for each bond finger 207 on the package substrate 201, which is expected to enable use of smaller bond fingers 207 (e.g., in comparison to the bond fingers 107 of FIG. 1 that must accommodate multiple tacks), lower the risk of failed connections or tacks (e.g., due to misalignment between a wire and a bond finger), and reduce the form factor/footprint of the bond shell as the bond fingers 207 can be placed closer to the semiconductor dies 203. Overall, the present technology is expected to shrink the footprint of the semiconductor device 200, or to allow additional semiconductor dies 203 to be placed on the stack 202 while maintaining a footprint comparable to the semiconductor device 100 of FIG. 1. Additionally, the present technology is expected to reduce the number and size of wire bonds 208 between the semiconductor dies 203 and the bond fingers 207, lowering manufacturing costs and the potential of failed connections and/or shorts.

Referring now to the DQ bond pads 212 of the second memory die 203b, because the second memory die 203b corresponds to the second byte 205 and not the first byte 204, these DQ bond pads 212 can remain active while not being used to access data on the second memory die 203b. In the illustrated embodiment, these DQ bond pads 212 have been left active but uncoupled from bond fingers 207 on the package substrate 201. In other embodiments, these DQ bond pads 212 can be converted to dummy pads 214 using the second circuitry 211b. In at least some of these embodiments, the converted dummy pads 214 on the second memory die 203b can be used to couple (i) DQ bond pads of a semiconductor die(s) (not shown) positioned higher in the stack 202 to (ii) corresponding bond fingers 207 on the package substrate 201, similar to how the dummy pads 214 of the first memory die 203a are employed.

Alternatively, the DQ bond pads 212 of the second memory die 203b can be coupled to corresponding bond fingers 207 on the package substrate 201 via cascaded wire bonds 209 that utilize the DQ bond pads 210 on the first memory die 203a. Continuing with this example, the DQ bond pads 212 of the second memory die 203b can be reversibly converted to dummy pads 214 by the second circuitry 211b when the semiconductor device 200 is operated in byte mode. Additionally, or alternatively, these DQ bond pads 212 can be used as DQ bond pads 210 to access data on the second memory die 203b, such as when the semiconductor device 200 is operated outside of byte mode and/or in an operation mode that transmits data to the second memory die 203b using both the first and second bytes 204 and 205.

Although described above in the context of converting unused DQ bond pads into dummy pads to facilitate using cascaded wire bonds, the present technology is not so limited. Indeed, converting unused power bond pads, unused command/address bond pads, unused chip select bond pads, or other unused bond pads into dummy pads to facilitate using cascaded wire bonds is within the scope of the present technology.

Furthermore, although shown in FIG. 2 with two semiconductor dies 203 in the stack 202, the present technology is not so limited. Indeed, semiconductor devices configured in accordance with other embodiments of the present technology can include stacks having any number of memory dies (e.g., one memory die, three memory dies, four or more memory dies). In one example, a stack of a semiconductor device includes three or more memory dies. Continuing with this example, when the semiconductor device operates in byte mode, a first memory die and a second memory die can be assigned to a first byte and a third memory die can be assigned to a second byte. In this example, DQ bond pads on the first memory die and/or on the second memory die in the stack can be converted into dummy pads using corresponding circuitry such that DQ bond pads and power bond pads on the third memory die can be coupled to bond fingers on a corresponding package substrate using cascaded wire bonds that utilize the dummy pads on the first memory die and/or the second memory die. Alternatively, DQ bond pads on the second memory die in the stack can be converted into dummy pads using corresponding circuitry such that DQ bond pads and/or power bond pads on the third memory die can be coupled to DQ bond pads and/or power bond pads, respectively, on the first memory die using cascaded wire bonds that utilize the dummy pads on the second memory die. In other words, the principles of the present technology can be extended to coupling bond pads on a semiconductor die to (i) bond fingers of a substrate and/or (ii) bond pads on another semiconductor die, using wire bonds that are cascaded down any number of intermediate semiconductor dies via dummy pads on one or more of the intermediate semiconductor dies.

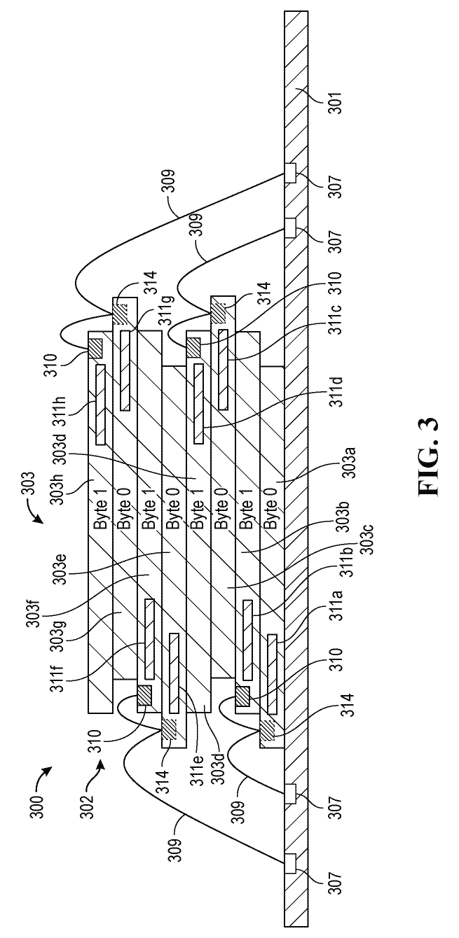

FIG. 3 is a partially schematic side view of another semiconductor device 300 configured in accordance with various embodiments of the present technology. The semiconductor device 300 is generally similar to the semiconductor device 200 of FIG. 2. Thus, similar reference numbers are used across FIGS. 2 and 3 to denote identical or at least generally similar components, and a detailed description of several aspects of the semiconductor device 300 of FIG. 3 is largely omitted here for the sake of brevity in view of the detailed description provided above with reference to FIG. 2.

As shown, the semiconductor device 300 of FIG. 3 includes a package substrate 301 having a plurality of bond fingers 307, and a stack 302 of semiconductor dies 303 (identified individually in FIG. 3 as first through eighth memory dies 303a-303h) disposed on the package substrate 301. It will be appreciated that the first and second memory dies 303a and 303b of FIG. 3 can be examples of the first and second memory dies 203a and 203b, respectively, of FIG. 2, or of other memory dies configured in accordance with various embodiments of the present technology.

In the illustrated example, the memory dies 303a-303h of the stack 302 are arranged in a reverse shingle 2-2-2-2 stack configuration such that (a) the first, second, fifth, and sixth memory dies 303a, 303b, 303e, and 303f are stacked over the package substrate 301 in a first orientation, and (b) the third, fourth, seventh, and eight memory dies 303c, 303d, 303g, and 303h are stacked over the package substrate 301 in a second orientation that is rotated 180 degrees relative to the first orientation about an axis that is generally perpendicular to the package substrate 301 and that extends generally vertically through a center of the stack 302. The first through eighth memory dies 303a-303h are shingled (e.g., staggered, tiered) in the stack 302 such that DQ bond pads 310 and/or dummy pads 314 of the memory dies 303a-303h are exposed to receive wire bond connections. For the sake of clarity and understanding, the semiconductor dies 303 are each shown to include one DQ bond pad 310 or one dummy pad 314. It should be understood, however, that each of the semiconductor dies 303 has a number of DQ bond pads 310 and/or dummy pads 314 (e.g., similar to the first and second memory dies 203a and 203b of FIG. 2) that are hidden in the side view provided by FIG. 3. In addition, other bond pads (e.g., other DQ bond pads, power bond pads, command/address (CA) bond pads, chip select (CS) bond pads, etc.) of the memory dies 303a-303h are not shown in FIG. 3 to avoid unnecessarily obscuring aspects of the present technology. Furthermore, as will become apparent from the description of FIG. 3 below, reference number 310 is used in FIG. 3 to denote an active DQ bond pad that is coupled to the package substrate 301 and used to access data on the corresponding semiconductor die 303, and reference number 314 is used in FIG. 3 to denote a dummy (or inactive) DQ bond pad that has been selectively disabled from being used to access data on the corresponding semiconductor die 303.

The semiconductor device 300 further includes circuitry 311. The circuitry 311 can be generally similar to the circuitry 211 (e.g., the first circuitry 211a and/or the second circuitry 211b) of FIG. 2. For example, consistent with the description of the first and second circuitry 211a and 211b of FIG. 2 above, the circuitry 311 can include one or more bond options, one or more fuse options, internal circuitry (e.g., switch networks), and/or other suitable components for selectively disabling/deactivating (or selectively enabling/activating) one or more DQ bond pads of the memory dies 303a-303h. In particular, the circuitry 311 can be configured to convert one or more DQ bond pads 310 of the memory dies 303a-303h into dummy pads 314, and/or vice versa. In the illustrated example, each of the memory dies 303a-303h includes corresponding circuitry 311 (circuitry 311a-311h corresponding to the first through eighth memory dies 303a-303h, respectively, are identified individually in FIG. 3). In other embodiments, the semiconductor device 300 can include circuitry 311 positioned at more locations than shown in FIG. 3 (e.g., on the package substrate 301, collocated on one or more of the memory dies 303a-303h) in addition to or in lieu of the circuitry 311a-311h shown in FIG. 3. Furthermore, although each of the circuitry 311a-311h is configured in FIG. 3 to selectively disable and/or enable DQ bond pads of only the corresponding semiconductor die 303, circuitry 311 configured in accordance with other embodiments of the present technology can be configured to selectively disable and/or enable DQ bond pads 310 or dummy pads 314, respectively, of a plurality of semiconductor dies 303 (e.g., all or a subset of the semiconductor dies 303 of the stack 302).

The semiconductor device 300 of FIG. 3 can be operated in byte mode. As shown in FIG. 3, the first, third, fifth, and seventh dies 303a, 303c, 303e, and 303g can be assigned to a first byte Byte 0; and the second, fourth, sixth, and eighth dies 303, 303d, 303f, and 303h can be assigned to a second byte Byte 1. Thus, consistent with the description of the present technology above with reference to FIG. 2, active bond pads (not shown) of the first, third, fifth, and seventh dies 303a, 303c, 303e, and 303g can be coupled to corresponding bond fingers (not shown) on the package substrate 301, such as using direct wire bonds (not shown).

In addition, because the first, third, fifth, and seventh dies 303a, 303c, 303e, and 303g are each assigned to the first byte Byte 0 and not to the second byte Byte 1 (at least while the semiconductor device 300 is operated in byte mode), DQ bond pads of the first, third, fifth, and seventh dies 303a, 303c, 303e, and 303g that correspond to the second byte Byte 1 on the first, third, fifth, and seventh dies 303a, 303c, 303e, and 303g can be converted into dummy pads 314 using the circuitry 311a, 311c, 311e, and 311g, respectively, such that the DQ bond pads are disconnected from internal circuitry (e.g., I/O circuitry) of the first, third, fifth, and seventh dies 303a, 303c, 303e, and 303g and/or are otherwise disabled from being used to access data on the first, third, fifth, and seventh dies 303a, 303c, 303e, and 303g. In turn, DQ bond pads 310 of the second, fourth, sixth, and eighth memory dies 303b, 303d, 303f, and 303h can be coupled to corresponding bond fingers 307 on the package substrate 301 via cascaded wire bonds 309 that utilize the dummy pads 314 of the first, third, fifth, and seventh memory dies 303a, 303c, 303e, and 303g, respectively. As a result, consistent with the description of FIG. 2 above, power wire bonds (not shown) of the semiconductor device 300 can be similarly cascaded to couple power bond pads (not shown) of the memory dies 303a-303h to corresponding bond fingers (not shown) on the package substrate 301.

Similar to the use of dummy pads 214 and cascaded wire bonds 208, 209 in the embodiment illustrated in FIG. 2, use of dummy pads 314, cascaded DQ wire bonds 309, and cascaded power wire bonds (not shown) in the semiconductor device 300 of FIG. 3 is expected to achieve several of the advantages of the present technology described above. For example, in comparison to the implementation illustrated in FIG. 1 in which the DQ bond pads 110 of the second memory die 103b are directly bonded to bond fingers 107 on the package substrate 101 using wire bonds 109, use of cascaded wire bonds 309 like those shown in FIG. 3 is expected to shorten the overall lengths of the wire bonds 309, thereby shortening the signal path (improving performance) and reducing manufacturing costs. In addition, in comparison to the present technology presented in FIG. 2, the illustrated configuration compounds these benefits by reducing the length of wire bonds 309 for additional memory dies 303c-303h positioned higher in the stack 302 than the first and second memory dies 303a and 303b, further reducing costs and increasing performance. Moreover, the use of cascaded DQ wire bonds 309 and cascaded power wire bonds (not shown) in lieu of direct wire bonds to couple DQ bond pads 310 and power bond pads (not shown), respectively, of the memory dies 303a-303h is also expected to achieve more compact wire routing, which may reduce the risk of wire bonds crossing and shorting. Furthermore, use of cascaded power wire bonds (not shown) in lieu of high/low loops is expected to reduce (e.g., to one) the number of tacks per corresponding bond finger (not shown) on the package substrate 301, thereby (a) enabling use of smaller bond fingers and/or bond fingers positioned closer to the stack 302 and/or (b) reducing the footprint of the bond shell and/or the form factor of the semiconductor device 300.

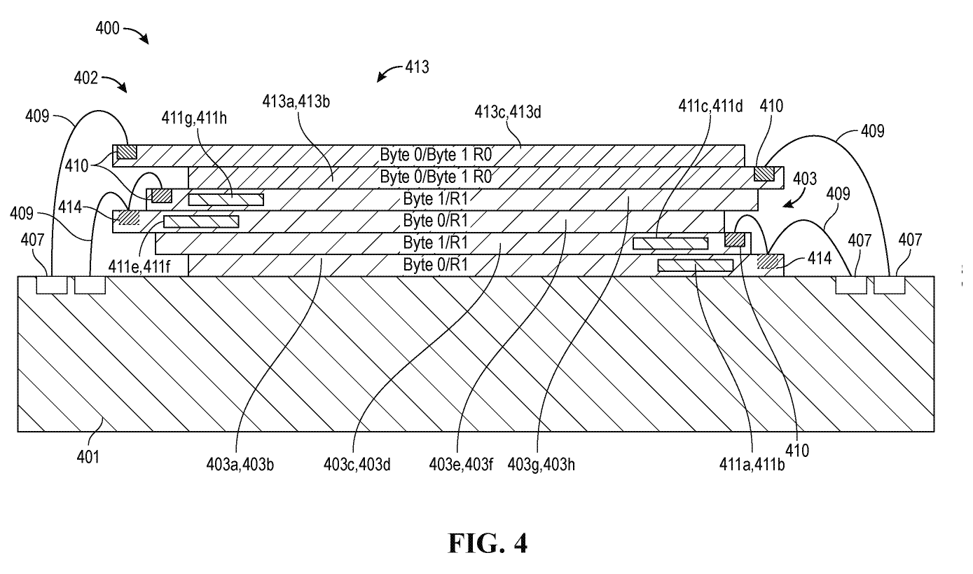

The principles of the present technology can be employed in semiconductor devices having other memory die densities, other memory die arrangements, and/or other substrate designs. For example, FIG. 4 is a partially schematic side view of still another semiconductor device 400 configured in accordance with various embodiments of the present technology. The semiconductor device 400 can be generally similar to the semiconductor devices 200 and 300 of FIGS. 2 and 3, respectively. Thus, similar reference numbers are used across FIGS. 2–4 to denote identical or at least generally similar components, and a detailed description of several aspects of the semiconductor device 400 of FIG. 4 is largely omitted here for the sake of brevity in light of the detailed description provided above with reference to FIGS. 2 and 3.

As shown, the semiconductor device 400 of FIG. 4 includes a package substrate 401 having a plurality of bond fingers 407, and a stack 402 of semiconductor dies 403, 413 (identified in FIG. 4 as first through eighth memory dies 403a-403h and ninth through twelfth memory dies 413a-413d) disposed on the package substrate 401. In contrast with the embodiments illustrated in FIGS. 2 and 3, each block illustrated in the stack 402 of FIG. 4 represents two semiconductor dies. In the illustrated example, the semiconductor dies 403, 413 of the stack 402 are arranged in a reverse shingle 4-4-2-2 stack configuration such that (a) the first through fourth memory dies 403a-403d and the ninth and tenth memory dies 413a and 413b are stacked over the package substrate 401 in a first orientation, and (b) the fifth through eighth memory dies 403e-403h and the eleventh and twelfth memory dies 413c and 413d are stacked over the package substrate 401 in a second orientation that is rotated 180 degrees relative to the first orientation about an axis that is generally perpendicular to the package substrate 401 and that extends generally vertically through a center of the stack 402. The first through twelfth memory dies 403a-403h, 413a-413d are shingled (e.g., staggered, tiered) in the stack 402 such that DQ bond pads 410 and/or dummy pads 414 of the semiconductor dies 403, 413 are exposed to receive wire bond connections.

The memory dies 403a-403h are each illustrated with corresponding circuitry 411 (identified in FIG. 4 as first through eighth circuitry 411a-411h, respectively). The circuitry 411 can be generally similar to the circuitry 211 and/or the circuitry 311 described in detail above with reference to FIGS. 2 and 3. For example, the circuitry 411a-411h can each include one or more bond options, one or more fuse options, circuitry (e.g., switch networks), and/or other components usable to selectively disable and/or enable one or more DQ bond pads 410 and/or dummy pads 414 of the corresponding semiconductor die 403, such as to convert one or more DQ bonds pads 410 of the memory dies 403a-403h to dummy pads 414 and/or vice versa. The memory dies 413a-413d do not include circuitry 411. In other embodiments of the present technology, one or more of the memory dies 413a-413d can include circuitry 411.

The memory dies 403a-403h and 413a-413d of the stack 402 are arranged into two ranks. More specifically, the memory dies 413a-413d are assigned to a first rank R0, and the memory dies 403a-403h are assigned to a second rank R1. In addition, as shown in FIG. 4, the memory dies 403a-403h are configured to operate in a X8 mode and are therefore assigned to either a first byte Byte 0 or a second byte Byte 1. In particular, the first, second, fifth, and sixth memory dies 403a, 403b, 403e, and 403f are assigned to the first byte Byte 0, and the third, fourth, seventh, and eighth memory dies 403c, 403d, 403g, and 403h are assigned to the second byte Byte 1. By contrast, the memory dies 413a-413d are each configured to operate in a X16 mode and are therefore assigned to both the first byte Byte 0 and the second byte Byte 1.

In some embodiments, the semiconductor device 400 can operate in byte mode and access data on the memory dies 403a-403h over a first two channels (e.g., a channel corresponding to the second rank R1 and the first byte Byte 0, and a channel corresponding to the second rank R1 and the second byte Byte 1). Thus, DQ bond pads (not shown) of the first, second, fifth, and sixth memory dies 403a, 403b, 403e, and 403f that correspond to the first byte Byte 0 can be coupled to corresponding bond fingers (not shown) on the package substrate 401 using direct wire bonds (not shown). In addition, the circuitry 411a, 411b, 411e, and 411f of the first, second, fifth, and sixth memory dies 403a, 403b, 403e, and 403f can convert DQ bond pads of the first, second, fifth, and sixth memory dies 403a, 403b, 403e, and 403f that correspond to the second byte Byte 1 to dummy pads 414 such that DQ bond pads 410 of the third, fourth, seventh, and eighth memory dies 403c, 403d, 403g, and 403h that correspond to the second byte Byte 1 can be coupled to corresponding bond fingers 407 on the package substrate 401 via cascaded wire bonds 409 that utilize the dummy pads 414 on the first, second, fifth, and/or sixth memory dies 403a, 403b, 403e, and/or 403f. As a result, at least with respect to memory dies 403a-403h, the semiconductor device 400 can realize several advantages of the present technology described herein.

By contrast, because the ninth through twelfth memory dies 413a-413d operate in the X16 mode, the semiconductor device 400 can utilize sixteen of the DQ bonds pads 410 (e.g., eight DQ bond pads 410 corresponding to the first byte Byte 0 and eight DQ bond pads 410 corresponding to the second byte Byte 1) of the memory dies 413a-413d to access data on the memory dies 413a-413d, such as over a second two channels (e.g., a channel corresponding to the first rank R0 and the first byte Byte 0, and a channel corresponding to the first rank R0 and the second byte Byte 1). As a result, in some embodiments, the sixteen DQ bond pads 410 of each of the memory dies 413a-413d can be coupled to corresponding bond fingers 407 on the package substrate 401 using direct wire bonds 409, as shown in FIG. 4.

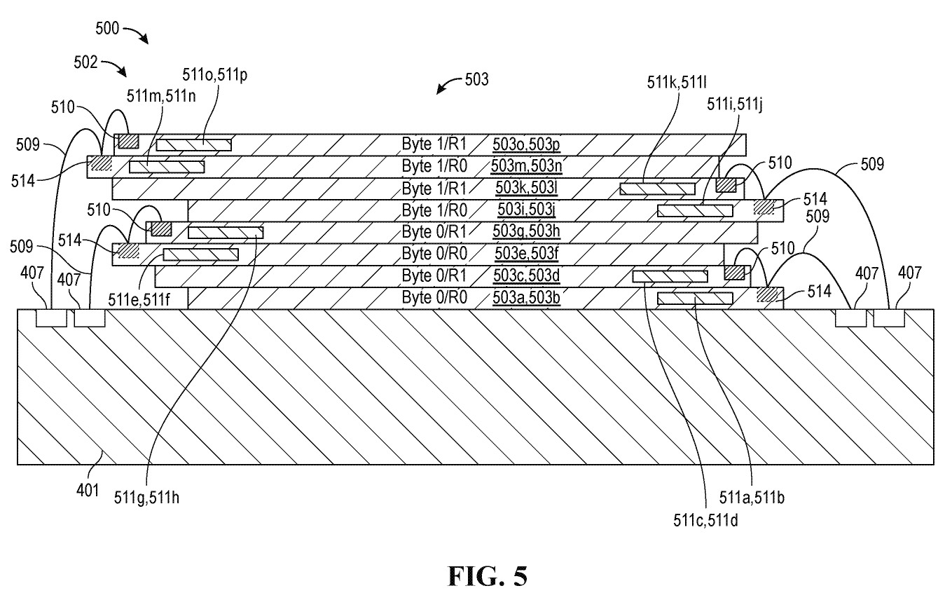

Now consider FIG. 5 that illustrates a partially schematic side view of yet another semiconductor device 500 configured in accordance with various embodiments of the present technology. The semiconductor device 500 can be generally similar to the semiconductor devices 200, 300, and 400 of FIGS. 2, 3, and 4, respectively. Thus, similar reference numbers are used across FIGS. 2–5 to denote identical or at least generally similar components, and a detailed description of several aspects of the semiconductor device 500 of FIG. 5 is largely omitted here for the sake of brevity in light of the detailed description provided above with reference to FIGS. 2–4.

As shown, the semiconductor device 400 of FIG. 4 includes the package substrate 401 from FIG. 4 but includes a stack 502 of semiconductor dies 503 having a different memory die density and arrangement from the stack 402 of the semiconductor device 400 of FIG. 4. In particular, the stack 502 of FIG. 5 includes sixteen (16) semiconductor dies 503 (identified in FIG. 5 as first through sixteenth memory dies 503a-503p) disposed on the package substrate 401. Similar to the embodiment illustrated in FIG. 4, each block illustrated in the stack 502 of FIG. 5 represents two semiconductor dies. In the illustrated example, the semiconductor dies 503 of the stack 502 are arranged in a reverse shingle 4-4-4-4 stack configuration such that (a) the first through fourth memory dies 503a-503d and ninth through twelfth memory dies 503i-503l are stacked over the package substrate 401 in a first orientation, and (b) the fifth through eighth memory dies 503e-503h and thirteenth through sixteenth memory dies 503m-503p are stacked over the package substrate 401 in a second orientation that is rotated 180 degrees relative to the first orientation about an axis that is generally perpendicular to the package substrate 401 and that extends generally vertically through a center of the stack 502. The first through sixteenth memory dies 503a-503p are shingled (e.g., staggered, tiered) in the stack 502 such that DQ bond pads 510 and/or dummy pads 514 of the semiconductor dies 503 are exposed to receive wire bond connections.

The memory dies 503a-503p are each illustrated with corresponding circuitry 511 (identified in FIG. 5 as first through sixteenth circuitry 511a-511p, respectively). The circuitry 511 can be generally similar to the circuitry 211, the circuitry 311, and/or the circuitry 411 described in detail above with reference to FIGS. 2, 3, and/or 4. For example, the circuitry 511a-511p can each include one or more bond options, one or more fuse options, circuitry (e.g., switch networks), and/or other components usable to selectively disable and/or enable one or more DQ bond pads 510 and/or dummy pads 514 of the corresponding semiconductor die 503, such as to convert one or more DQ bonds pads 510 of the memory dies 503a-503p to dummy pads 514 and/or vice versa.

Similar to the memory dies 403a-403h and 413a-413d of FIG. 4, the memory dies 503a-503p of FIG. 5 are arranged into two ranks. In the embodiment illustrated in FIG. 5, however, the first, second, fifth, sixth, ninth, tenth, thirteenth, and fourteenth memory dies 503a, 503b, 503e, 503f, 503i, 503j, 503m, and 503n are assigned to a first rank R0; and the third, fourth, seventh, eighth, eleventh, twelfth, fifteenth, and sixteenth memory dies 503c, 503d, 503g, 503h, 503k, 503l, 503o, and 503p are assigned to a second rank R1. In addition, as shown in FIG. 5, each of the memory dies 503a-503p are configured to operate in a X8 mode and are therefore assigned to either a first byte Byte 0 or a second byte Byte 1. In particular, the first through eighth memory dies 503a-503h are assigned to the first byte Byte 0; and ninth through sixteenth memory dies 503i-503p are assigned to the second byte Byte 1.

In some embodiments, the semiconductor device 500 can operate in byte mode and access data on the memory dies 503a-503p using the four channels described above with reference to FIG. 4. For example, data can be accessed on the first, second, fifth, and sixth memory dies 503a, 503b, 503e, and 503f using a first channel corresponding to the first rank R0 and the first byte Byte 0; and data can be accessed on the third, fourth, seventh, and eighth memory dies 503c, 503d, 503g, and 503h using a second channel corresponding to the second rank R1 and the first byte Byte 0. Similarly, data can be accessed on the ninth, tenth, thirteenth, and fourteenth memory dies 503i, 503j, 503m, and 503n using a third channel corresponding to the first rank R0 and the second byte Byte 1; and data can be accessed on the eleventh, twelfth, fifteenth, and sixteenth memory dies 503k, 503l, 503o, and 503p using a fourth channel corresponding to the second rank R1 and the second byte Byte 1.

DQ bond pads (not shown) of the first, second, fifth, sixth, ninth, tenth, thirteenth, and fourteenth memory dies 503a, 503b, 503e, 503f, 503i, 503j, 503m, and 503n can be coupled to corresponding bond fingers (not shown) on the package substrate 401 using direct wire bonds (not shown). In addition, the circuitry 511a, 511b, 511e, 511f, 511i, 511j, 511m, and 511n of the first, second, fifth, sixth, ninth, tenth, thirteenth, and fourteenth memory dies 503a, 503b, 503e, 503f, 503i, 503j, 503m, and 503n, respectively, can convert DQ bond pads of the first, second, fifth, sixth, ninth, tenth, thirteenth, and fourteenth memory dies 503a, 503b, 503e, 503f, 503i, 503j, 503m, and 503n to dummy pads 514 such that DQ bond pads 510 of the third, fourth, seventh, eighth, eleventh, twelfth, fifteenth, and sixteenth memory dies 503c, 503d, 503g, 503h, 503k, 503l, 503o, and 503p can be coupled to corresponding bond fingers 407 on the package substrate 401 via cascaded wire bonds 509 that utilize the dummy pads 514 on the first, second, fifth, sixth, ninth, tenth, thirteenth, and fourteenth memory dies 503a, 503b, 503e, 503f, 503i, 503j, 503m, and 503n. As a result, the semiconductor device 500 can realize several advantages of the present technology described herein. In addition, as evidenced by the same package substrate 401 accommodating both the stack 402 of FIG. 4 and the stack 502 of FIG. 5, the present technology can facilitate using a same substrate design (e.g., bond finger layout) with different die densities and/or configurations, which is expected to reduce manufacturing and/or assembly costs in comparison to substrate designs with limited versatility.

### C.Conclusion

The above detailed descriptions of embodiments of the technology are not intended to be exhaustive or to limit the technology to the precise form disclosed above. Although specific embodiments of, and examples for, the technology are described above for illustrative purposes, various equivalent modifications are possible within the scope of the technology as those skilled in the relevant art will recognize. For example, although steps are presented in a given order above, alternative embodiments may perform steps in a different order. Furthermore, the various embodiments described herein may also be combined to provide further embodiments.

From the foregoing, it will be appreciated that specific embodiments of the technology have been described herein for purposes of illustration, but well-known structures and functions have not been shown or described in detail to avoid unnecessarily obscuring the description of the embodiments of the technology.

Where the context permits, singular or plural terms may also include the plural or singular term, respectively. In addition, unless the word “or” is expressly limited to mean only a single item exclusive from the other items in reference to a list of two or more items, then the use of “or” in such a list is to be interpreted as including (a) any single item in the list, (b) all of the items in the list, or (c) any combination of the items in the list. Furthermore, as used herein, the phrase “and/or” as in “A and/or B” refers to A alone, B alone, and both A and B. Additionally, the terms “comprising,” “including,” “having,” and “with” are used throughout to mean including at least the recited feature(s) such that any greater number of the same features and/or additional types of other features are not precluded. Moreover, as used herein, the phrases “based on,” “depends on,” “as a result of,” and “in response to” shall not be construed as a reference to a closed set of conditions. For example, an exemplary step that is described as “based on condition A” may be based on both condition A and condition B without departing from the scope of the present disclosure. In other words, as used herein, the phrase “based on” shall be construed in the same manner as the phrase “based at least in part on” or the phrase “based at least partially on.”

From the foregoing, it will also be appreciated that various modifications may be made without deviating from the disclosure or the technology. For example, one of ordinary skill in the art will understand that various components of the technology can be further divided into subcomponents, or that various components and functions of the technology may be combined and integrated. In addition, certain aspects of the technology described in the context of particular embodiments may also be combined or eliminated in other embodiments. Furthermore, although advantages associated with certain embodiments of the technology have been described in the context of those embodiments, other embodiments may also exhibit such advantages, and not all embodiments need necessarily exhibit such advantages to fall within the scope of the technology. Accordingly, the disclosure and associated technology can encompass other embodiments not expressly shown or described herein.

We claim:

1. A semiconductor device, comprising:
a substrate including a bond finger;
a stack of semiconductor dies disposed on the substrate, the stack including a first semiconductor die and a second semiconductor die disposed over the first semiconductor die, wherein the first semiconductor die includes a dummy pad, and wherein the second semiconductor die includes a bond pad; and
a cascaded wire bond coupling the bond pad to the bond finger via the dummy pad.

2. The semiconductor device of claim 1, further comprising circuitry configured to convert a bond pad of the first semiconductor die into the dummy pad.

3. The semiconductor device of claim 2, wherein the circuitry includes a fuse option usable to convert the bond pad of the first semiconductor die into the dummy pad.

4. The semiconductor device of claim 2, wherein the circuitry includes a bond option usable to convert the bond pad of the first semiconductor die into the dummy pad.

5. The semiconductor device of claim 2, wherein the circuitry includes a switch network usable to toggle the bond pad of the first semiconductor die between being configured as the dummy pad and being configured as an active bond pad.

6. The semiconductor device of claim 2, wherein the first semiconductor die includes the circuitry.

7. The semiconductor device of claim 1, wherein the semiconductor device is configured to operate in a byte mode, and wherein the dummy pad is a disabled data (DQ) bond pad associated with an unused byte of the first semiconductor die.

8. The semiconductor device of claim 1, wherein:
the cascaded wire bond is a first cascaded wire bond;
the first semiconductor die includes a first power bond pad and the second semiconductor die includes a second power bond pad;
the bond finger is a first bond finger and the substrate includes a second bond finger; and
the semiconductor device further comprises a second cascaded wire bond coupling the first and second power bond pads to the second bond finger.

9. The semiconductor device of claim 8, wherein the second cascaded wire bond is configured to provide shielding for the first cascaded wire bond.

10. The semiconductor device of claim 8, wherein the first and second bond fingers each include only one tack, and wherein the only one tack of the first and second bond fingers corresponds to the first cascaded wire bond and the second cascaded wire bond, respectively.

11. A memory device, comprising:
a substrate;
a first memory die and a second memory die arranged in a stack over the substrate; and
circuitry, wherein the first memory die includes a bond pad disabled by the circuitry.

12. The memory device of claim 11, wherein:
the bond pad is a disabled bond pad;
the second memory die includes an enabled bond pad; and
the memory device further comprises a cascaded wire bond coupling the enabled bond pad to the substrate via the disabled bond pad.

13. The memory device of claim 12, wherein:
the memory device is configured to operate in a byte mode; and
the disabled bond pad is a disabled data (DQ) bond pad corresponding to an unused byte of the first memory die while the memory device is operated in the byte mode.

14. The memory device of claim 13, wherein the enabled bond pad is an enabled DQ bond pad corresponding to a used byte of the second memory die while the memory device is operated in the byte mode.

15. The memory device of claim 12, wherein:
the cascaded wire bond is a first cascaded wire bond;
the first memory die further includes a first power bond pad;
the second memory die further includes a second power bond pad; and
the memory device further comprises a second cascaded wire bond (a) coupling the first and second power bond pads to the substrate and (b) configured to shield the first cascaded wire bond.

16. The memory device of claim 12, further comprising a third memory die and a fourth memory die reverse shingle stacked on the first memory die and the second memory die, wherein:
the circuitry is first circuitry, the disabled bond pad is a first disabled bond pad, the enabled bond pad is a first enabled bond pad, and the cascaded wire bond is a first cascaded wire bond;
the memory device further comprises second circuitry and a second cascaded wire bond;
the third memory die includes a second disabled bond pad that is disabled by the second circuitry;
the fourth memory die includes a second enabled bond pad; and
the second cascaded wire bond couples the second enabled bond pad to the substrate via the second disabled bond pad.

17. The memory device of claim 11, wherein the bond pad is disabled via a fuse or a bond option of the circuitry.

18. A method of operating a semiconductor device, the method comprising:
disposing a stack of semiconductor dies on a substrate, the stack including a first semiconductor die and a second semiconductor die;
converting a bond pad of the first semiconductor die into a dummy pad; and
connecting, using a cascaded wire bond, a bond pad of the second semiconductor die to a bond finger of the substrate via the dummy pad.

19. The method of claim 18, wherein converting the bond pad of the first semiconductor die into the dummy pad comprises blowing a fuse of the semiconductor device.

20. The method of claim 18, wherein converting the bond pad of the first semiconductor die into the dummy pad comprises converting the bond pad of the first semiconductor die into the dummy pad using a bond option of the semiconductor device.
